(19) United States
(12) Patent Application Publication
(10) Pub. No.: US 2018/0236522 A1
(43) Pub. Date: Aug. 23, 2018

(54) COATING FILM, HOT-FORMING DIE, AND HOT FORMING METHOD

(71) Applicant: KABUSHIKI KAISHA KOBE SEIKO SHO (Kobe Steel, Ltd.), Kobe-shi (JP)

(72) Inventor: Kenji YAMAMOTO, Kobe-shi (JP)

(73) Assignee: KABUSHIKI KAISHA KOBE SEIKO SHO (Kobe Steel, Ltd.), Kobe-shi (JP)

(21) Appl. No.: 15/749,524

(22) PCT Filed: Aug. 23, 2016
(86) PCT No.: PCT/JP2016/074500

§ 371 Date: Feb. 1, 2018

(30) Foreign Application Priority Data
Aug. 31, 2015 (JP) 2015-170195

(51) Int. Cl. B21D 37/01; B21D 37/20; C23C 14/06

(52) U.S. Cl. CPC B21D 37/01; B21D 22/208; C23C 14/0635; B21D 37/20

(57) ABSTRACT

A coating film 12 is a coating film to be formed as a wear resistant layer in a hot-forming die 1 for hot forming of a steel plate 10. The coating film 12 is made of tungsten carbide and 3 weight % or more and 15 weight % or less of remaining cobalt. The hot-forming die 1 is a hot-forming die for hot forming of the steel plate 10, and comprises a base material 11 having a forming surface 11A and the coating film 12 which is formed on the forming surface 11A. A hot forming method comprises a step of heating the steel plate 10 and a step of forming the steel plate 10 which is heated by using the hot-forming die 1.

### TECHNICAL FIELD

The present invention relates to a coating film, a hot-forming die and a hot forming method.

### BACKGROUND ART

It is conventionally known to form a coating film layer being made of a metal ceramic composite on a surface of a die for hot forming aiming at improving wear resistance and thermal shock resistance. A technique of this kind is disclosed in Patent Literature 1 set forth below. Patent Literature 1 below discloses a lamination of an underlying layer formed of a metal layer containing any one of titanium (Ti), zirconium (Zr) and hafnium (Hf), and a surface layer formed of a composite nitride layer represented by a composition formula of (Ti₁₋ₓAlₓ)N on a base material surface of a die for hot forming.

In the die disclosed in Patent Literature 1 below, a generation of cracks can be suppressed because an abrupt heat transmission between the surface layer and the base material is alleviated by forming the underlying layer between the base material and the surface layer having thermal conductivities largely different from each other. The underlying layer has an intermediate thermal conductivity between the surface layer and the base material. However, the die has a problem that when used in hot forming of a body to be formed which is made of steel, sufficient wear resistance cannot be obtained by the surface layer formed of a composite nitride of Ti and Al.

### CITATION LIST

### Patent Literature

Patent Literature 1: Japanese Patent Unexamined Publication No. 2013-146778

### SUMMARY OF INVENTION

An object of the present invention is to provide a coating film functioning as an excellent wear resistant layer in a hot-forming die for steel, a hot-forming die including the coating film, and a hot forming method using the hot-forming die.

A coating film according to one aspect of the present invention is a coating film to be formed as a wear resistant layer in a die for hot forming of a body to be formed which is made of steel. The coating film is characterized in being made of tungsten carbide and 3 weight % or more and 15 weight % or less of cobalt.

### BRIEF DESCRIPTION OF DRAWINGS

FIG. 1 is a schematic view showing a configuration of a hot-forming die according to an embodiment of the present invention.

FIG. 2 is a schematic view showing a coating formation device which forms a coating film in the hot-forming die.

FIG. 3 is a flowchart showing a flow of a hot forming method to be performed using the hot-forming die.

### DESCRIPTION OF EMBODIMENTS

In the following, an embodiment of the present invention will be described in detail on the basis of the drawings.

First, outlines of a coating film, a hot-forming die and a hot forming method according to the embodiment of the present invention will be described.

The coating film according to the present embodiment is a coating film to be formed as a wear resistant layer in a die for hot forming of a body to be formed which is made of steel. The coating film is characterized in being made of tungsten carbide and 3 weight % or more and 15 weight % or less of cobalt.

As a result of intensive research for providing an excellent wear resistant layer for use in a hot-forming die for steel, the present inventors have obtained the following knowledge to arrive at the present invention.

As one method of hot forming of steel, a hot pressing (die quenching) method in which after steel is heated at a high temperature, the steel is formed by a die as well as being quenched by cooling is applicable. In the present embodiment, description will be made in the following with respect to a die for use in a hot pressing method as one example of a hot forming method of steel. As the other hot forming method except a hot pressing, a hot forging is applicable. Here, in high temperature heating, an oxide layer (scale) mainly made of iron oxide is formed on a surface of steel. Scales have a thickness of several μm to several tens μm, and have an inner layer of FeO and an outer layer of Fe₂O₃ and Fe₃O₄. The thickness of scales varies depending on compositions of steel or forming condition. The present inventors note that the die is damaged by wear caused by sliding of the scale and the die when forming steel in which the scale is formed by the die. The present inventors have conducted search to find a measure for preventing the damage. As a result, the present inventors have found that wear resistance is drastically improved when a coating film which includes tungsten carbide (WC) as a main component and includes 3 weight % or more and 15 weight % or less of cobalt (Co) is used as a wear resistant layer.

The coating film according to the present embodiment is made of WC and 3 weight % or more and 15 weight % or less of remaining Co, and functions as an excellent wear resistant layer in a hot-forming die for steel. When a Co content is less than 3 weight %, the coating film is fragile, so that at the time of formation, the coating film breaks off to advance damage. By contrast, when the Co content exceeds 15 weight %, much soft Co is present in the coating film so that a wearing speed is increased. Therefore, the Co content is within a range of 3 weight % or more and 15 weight % or less and is preferably within a range of 5 weight % or more and 10 weight % or less.

The coating film which is made of WC and the remaining Co, may include inevitably mixed impurities.

In terms of ensuring durability, a thickness of the coating film is preferably 10 μm or more, more preferably 50 μm or more, and still more preferably 100 μm or more.

The coating film can be formed by a thermal spraying method. Additionally, when a cross-section of the coating film is observed at a 2000× magnification, sizes of 95% or more of particles of tungsten carbide in the coating film may be the sizes included in a circle with a diameter of 10 μm.

When individual particles of tungsten carbide constituting the coating film are large, the particles of tungsten carbide drop off during sliding of the coating film and a body to be formed, causing wear due to missing of particles on a sliding surface. By contrast, setting sizes of 95% or more of the particles of tungsten carbide to fall within a circle with a diameter of 10 μm prevents the particles during sliding from dropping off.

In the coating film, the body to be formed can be made of steel including 0.5 weight % or more and 3 weight % or less of silicon. Additionally, the body to be formed can be made of steel including 0.05 weight % or more and 1.0 weight % or less of chrome.

When components of steel include elements of silicon (Si) and chrome (Cr), a growth rate of a scale is reduced, so that the scale is formed to be thin as a whole to make scale components of Fe₂O₃ and Fe₃O₄ rich. Since these scale components are components harder than FeO, an amount of wear of the die is liable to be increased in hot forming of the steel including Si and Cr. To cope with the increase, use of the coating film according to the present embodiment as a wear resistant layer prevents an increase in an amount of wear also in hot forming steel including Si and Cr as compared with a case where a conventional coating film is used.

Contents of Si and Cr are defined to be within the range due to properties of steel constituting a body to be formed. With an increase in Si and Cr contents, scale components of Fe₂O₃ and Fe₃O₄ are increased to increase an amount of wear of the die. When the Cr content is 0.05 weight % or more, a scale composition is affected, and in particular, when the Cr content is 0.1 weight % or more, effects on a scale composition is conspicuous.

In the coating film, the body to be formed can be made of steel including 0.15 weight % or more and 0.35 weight % or less of carbon.

Similarly to Si and Cr, a content of carbon (C) is defined to be within the range due to properties of steel constituting a body to be formed. Additionally, the steel can include, as other elements than C, Si, and Cr, manganese (Mn), phosphor (P), sulfur (S), titanium (Ti), boron (B) or Al. Contents of these elements can be several weight % or less.

The hot-forming die according to the present embodiment is a hot-forming die for hot forming of a body to be formed which is made of steel. The hot-forming die is provided with a base material having a forming surface and the coating film according to the present embodiment which is formed on the forming surface.

In the hot-forming die, the coating film made of WC and 3 weight % or more and 15 weight % or less of remaining Co is formed on the base material. This suppresses, even when hot forming of a body to be formed made of steel is conducted, the die from being damaged due to wear caused by scales formed on the surface of the steel.

A hot forming method according to the present embodiment includes a step of heating a body to be formed which is made of steel, and a step of forming the heated body to be formed. In the forming step, the body to be formed is formed using the hot-forming die according to the present embodiment.

In the hot forming method, a body to be formed is formed using the hot-forming die with the coating film formed which is made of WC and 3 weight % or more and 15 weight % or less of remaining Co. Therefore, it is possible to suppress the surface of the die from being damaged due to wear caused by scales produced in the step of heating a body to be formed. This improves durability of the die, thereby gaining an advantage of increasing a maintenance interval of the die during hot forming.

[Hot-Forming Die]

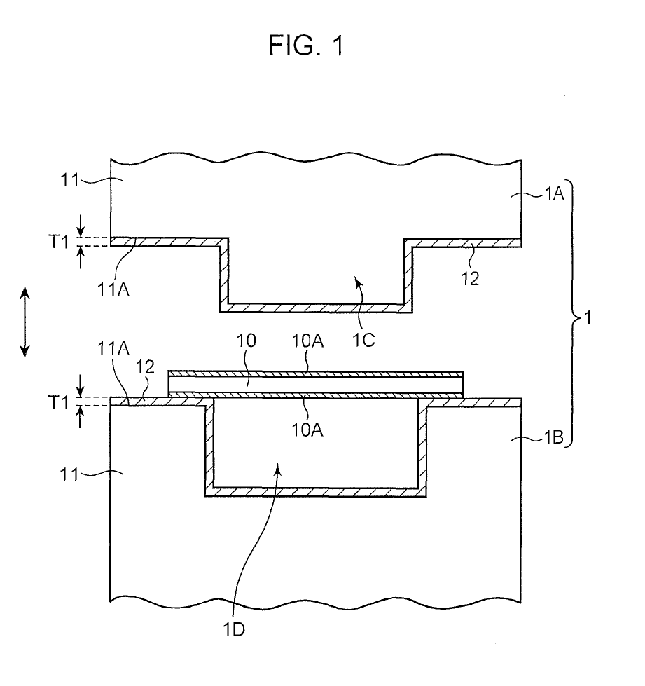

Next, a hot-forming die 1 according to the embodiment of the present invention will be described with reference to FIG. 1. FIG. 1 shows a state where in the hot-forming die 1, a steel plate 10 which is a body to be formed is disposed.

The hot-forming die 1 is a die for hot forming of the steel plate 10, and comprises an upper die 1A and a lower die 1B which are arranged spaced apart from each other in an up-down direction (an arrow in FIG. 1). The upper die 1A has a protrusion portion 1C, and the lower die 1B has a recessed portion 1D which engages with the protrusion portion 1C. The upper die 1A and the lower die 1B are allowed to be displaced so as to come closer to each other or to be apart from each other by driving force from a drive source not shown. As shown in FIG. 1, with the heated steel plate 10 being disposed on the lower die 1B, the upper die 1A is lowered without a time delay so as to prevent a temperature of the steel plate from decreasing. As a result, the steel plate 10 is pressed by the protrusion portion 1C, so that the steel plate 10 can be formed into a shape following the recessed portion 1D of the lower die 1B.

Each of the upper die 1A and the lower die 1B has a base material 11 and a coating film 12 which is formed on the base material 11. The base material 11 is a member made of metal constituting a main body of the hot-forming die 1, and has a forming surface 11A as a surface which presses the steel plate 10 during hot forming. The protrusion portion 1C is a part protruding from the forming surface 11A of the upper die 1A to the lower die 1B side, and the recessed portion 1D is a part recessed from the forming surface 11A of the lower die 1B to a side opposite to the upper die 1A. The coating film 12 is formed on the forming surface 11 as a wear resistant layer of the hot-forming die 1.

The coating film 12 is made of WC and remaining Co which is a binding agent (binder) which binds WC particles to each other. The coating film 12 preferably has a thickness T1 of 10 μm or more in terms of ensuring durability of a film, more preferably has the thickness T1 of 50 μm or more, and still more preferably has the thickness T1 of 100 μm or more.

The coating film 12 is obtained by forming a sintered body including a mixture of WC and Co on the forming surface 11A by a PVD (Physical Vapor Deposition) method or a thermal spraying method. As the PVD method, a sputtering method or an arc ion plating method can be used. Additionally, as the thermal spraying method, plasma thermal spraying or HVOF (High Velocity Oxygen Flame) can be used. In the thermal spraying method, spraying WC and Co sintered body powder to the base material 11 at a high speed forms the coating film 12. Since this method has a high film-forming speed, the method is suitable for formation of a thick film with the thickness T1 of 50 μm or more.

When the coating film 12 is formed by the thermal spraying method, tungsten carbide (WC) is formed by using a powdered material as described above. Here, 95% or more of WC particles ultimately included in the coating film 12 are included in a circle with a diameter of 10 μm. In other words, 95% or more of WC particles included in the coating film 12 have a maximum length in each direction of 10 μm or less. As a method for observing a size of WC particles, an observation method can be adopted which uses an SEM (Scanning Electron Microscope). Specifically, the coating film 12 is cut in a thickness direction, and a cross-section thereof can be observed by an SEM or the like at an approximately 2000× magnification within a field of vision of approximately 100 μm×100 μm. Then, sizes of individual WC particles within the field of vision can be measured.

Since the thermal spraying method has a high film-forming rate, such a thick film having the thickness T1 of 50 μm or more as described above can be formed. However, when individual WC particles constituting the coating film 12 are large, WC particles drop off during sliding of the hot-forming die 1 and the steel plate 10, causing wear due to missing of particles on the slide surface. For preventing the wear, when cross-section observation of the coating film 12 is conducted as described above, at least 95% or more of WC particles should be included in a circle with a diameter of 10 μm. Additionally, it is more preferable that at least 95% or more of WC particles are included in a circle with a diameter of 5 μm or less.

In the coating film 12, the Co content is adjusted to be 3 weight % (wt %) or more. When the Co content is less than 3 wt %, the coating film 12 is fragile, so that during hot forming of the steel plate 10, the coating film 12 breaks off to advance damage of the coating film 12 in some cases. In terms of preventing the damage, the Co content is set to be 3 wt % or more, more preferably 4 wt % or more, and still more preferably 5 wt % or more.

In the coating film 12, the Co content is adjusted to be 15 wt % or less. When the Co content exceeds 15 wt %, the amount of soft Co is excessive in the coating film 12, so that a wearing speed of the coating film 12 is increased. Therefore, the Co content is set to be 15 wt % or less, preferably 12 wt % or less, and still more preferably 10 wt % or less.

The Co content of the coating film 12 can be measured using EDX (Energy Dispersion X-ray Spectroscopy) analysis.

The steel plate 10 is a body to be formed which is hot formed using the hot-forming die 1. The steel plate 10 includes 0.15 wt % or more and 0.35 wt % or less of C, 0.5 wt % or more and 3 wt % or less of Si and 0.05 wt % or more and 1.0 wt % or less of Cr, and is made of remaining iron and impurities. The Si content may be 1 wt % or more, may be 1.5 wt % or more, and may be 2.5 wt % or more. Additionally, the Cr content may be 0.1 wt % or more, and may be 0.5 wt % or more.

The steel plate 10 is not limited to that having the above component composition, but may be a steel plate not including Cr in which Si content is in the above range, or a steel plate not including Si in which Cr content is in the above range, or a steel plate including none of component elements of C, Si and Cr. Additionally, other component elements such as Mn, P, S, Ti, B or Al may be further included, a content of which may be several wt % or less.

The steel plate 10 is subjected to heating process under atmosphere in a heating furnace not shown before being disposed in the hot-forming die 1 as shown in FIG. 1. At this time, an iron component constituting the steel plate 10 is oxidized by oxygen in atmosphere to form a thin scale (oxide layer) 10A on the surface of the steel plate 10. The scale 10A mainly includes iron oxides such as FeO, Fe₂O₃, Fe₃O₄, etc., and has an inner side mainly including FeO and has an outer side mainly including Fe₂O₃ and Fe₃O₄. In particular, since the steel plate 10 includes component elements of Si and Cr, the steel plate 10 produces the scale 10A which includes larger amounts of Fe₂O₃ and Fe₃O₄ than the steel plate not including Si and Cr. Fe₂O₃ and Fe₃O₄ are oxides having higher hardness than FeO.

At the time of hot forming of the steel plate 10, the scale 10A formed on the surface of the steel plate 10 and the surface of the hot-forming die 1 come into contact with each other to slide. For suppressing wear of the die due to the sliding, in the hot-forming die 1 according to the present embodiment, the coating film 12 is formed as a wear resistant layer on the base material 11. In other words, since at the time of hot forming of the steel plate 10, the base material 11 does not directly contact the scale 10A, but the coating film 12 and the scale 10A contact with each other, it is possible to suppress the base material 11 from being damaged due to wear caused by sliding with the scale 10A.

[Coating Film Forming Method]

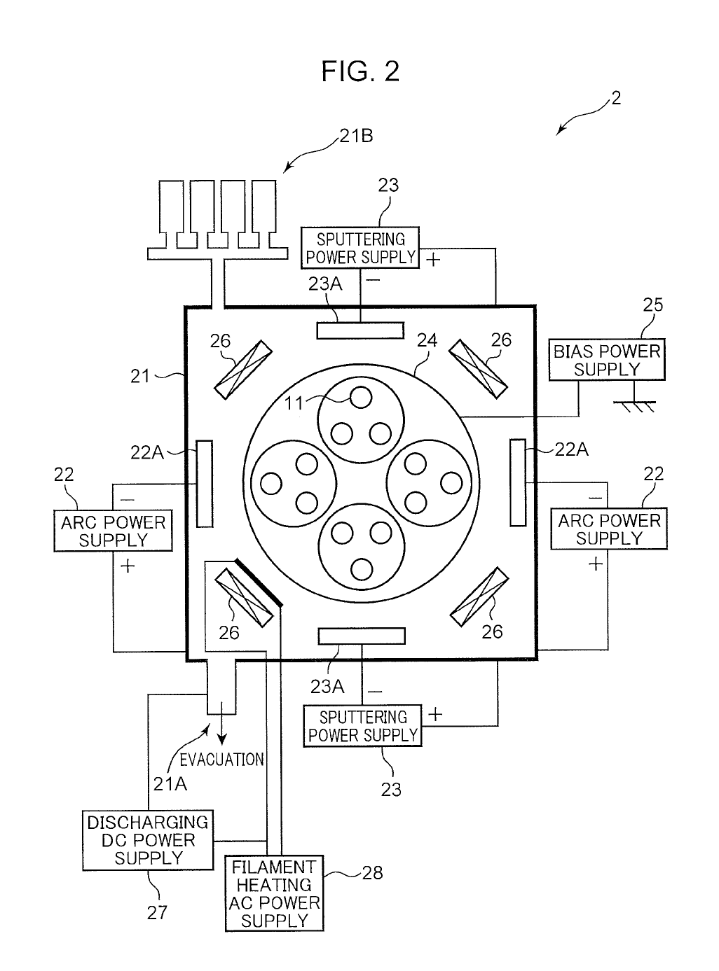

Next, description will be made of a procedure of forming the coating film 12. FIG. 2 shows a device configuration of a film-forming device 2 for use in film-forming of the coating film 12. First, the configuration of the film-forming device 2 will be described with reference to FIG. 2.

The film-forming device 2 comprises a chamber 21, a plurality of (two) arc power supplies 22 and sputtering power supplies 23, a base material stage 24, a bias power supply 25, a plurality of (four) heaters 26, a discharging DC power supply 27 and a filament heating AC power supply 28. The chamber 21 is provided with a gas exhaust port 21A for evacuation and a gas supply port 21B for supplying gas into the chamber 21. An arc evaporation source 22A on which a target is arranged is connected to the arc power supply 22. A sputtering evaporation source 23A on which a target is arranged is connected to the sputtering power supply 23. The base material stage 24 is configured to be rotatable, and has a supporting surface for supporting the base material 11 as a target of film forming. The bias power supply 25 applies a negative bias to the base material 11 through the base material stage 24.

Next, a procedure of forming the coating film 12 on the base material 11 will be described. In the present embodiment, description will be made of film-forming of the coating film 12 by an arc ion plating method.

First, the base material 11 is prepared, and is set on the base material stage 24. On the other hand, a WC—Co sintered body adjusted to have a Co content of 3 wt % or more and 15 wt % or less is prepared, and is set to the arc evaporation source 22A as a target for film-forming.

Next, a pressure in the chamber 21 is reduced to a predetermined pressure through the gas exhaust port 21A to enter a vacuum state. Next, Ar gas is introduced from the gas supply port 21B into the chamber 21, and the base material 11 is heated by the heater 26 to a predetermined temperature. Then, the surface of the base material 11 is etched with Ar ions for a predetermined time. This removes an oxide coating film formed on the surface of the base material 11, and the like.

Next, by flowing a predetermined arc current, a target set to the arc evaporation source 22A is evaporated, while the base material stage 24 is rotated at a predetermined rotation speed. This causes the evaporated target to be attached on the base material 11 to form the coating film 12. The film-forming speed is adjusted by conditions of an arc current or conditions of a rotation speed of the base material stage 24, and a film-forming time is adjusted to reach a desired film thickness.

Then, after reaching the desired film thickness, supply of an arc current and rotation of the base material stage 24 are stopped. Thereafter, the inside of the chamber 21 is opened to atmosphere, and the base material 11 after the film formation is taken out from the chamber 21. With the foregoing procedure, the coating film 12 is formed on the base material 11.

Additionally, for forming the coating film 12 by the sputtering method, a WC—Co sintered body with a Co content adjusted to be 3 wt % or more and 15 wt % or less is set in the sputtering evaporation source 23A as a target. Then, applying predetermined electric power to the sputtering evaporation source 23A evaporates the target and rotates the base material stage 24, thereby forming the coating film 12.

[Hot Forming Method]

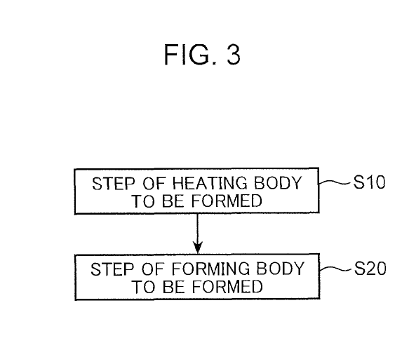

Next, following the flowchart of FIG. 3, description will be made of a hot forming method performed using the hot-forming die 1 in which the coating film 12 is formed as a wear resistant layer. The hot forming method is performed by a hot pressing (die quenching) method in which forming of the steel plate 10 and quench-hardening by cooling are simultaneously performed.

First, Step S10 is performed for heating a body to be formed. In Step S10, first, as a body to be formed which is to be subjected to hot forming, the steel plate 10 processed to be a flat plate is prepared which includes 0.15 wt % or more and 0.35 wt % or less of C, 0.5 wt % or more and 3 wt % or less of Si and 0.05 wt % or more and 1.0 wt % or less of Cr, and is made of remaining iron and impurities.

Next, the steel plate 10 is arranged in a heating furnace (not shown), and is heated to a predetermined temperature (on the order of 900° C.) until the plate becomes austenite under atmosphere. As a result of this heating, the scale 10A mainly including iron oxides such as FeO, Fe₂O₃, Fe₃O₄, etc. is formed on the surface of the steel plate 10 (FIG. 1).

Next, Step S20 is performed for forming a body to be formed. In Step S20, as shown in FIG. 1, the steel plate 10 heated in the Step S10 is transported to the hot-forming die 1 by a predetermined transportation means (not shown), and is disposed on the lower die LB. Next, by a driving force from a drive source (not shown), the upper die 1A is lowered toward the lower die 1B. As a result, the steel plate 10 is pressed by the protrusion portion 1C of the upper die 1A, resulting in press-forming the steel plate 10 into a shape of the recessed portion 1D of the lower die 1B. Simultaneously with the press-forming, the steel plate 10 is maintained in a state of being in contact with the hot-forming die 1 for a predetermined time, resulting in being rapidly cooled to a temperature below an Ms point (martensitic transformation point) so as to be quench-hardened.

In this step (S20), for conducting press-forming of the steel plate 10, the scale 10A formed on the surface of the steel plate 10 comes into contact with the hot-forming die 1. Here, when the coating film 12 is not formed on the base material 11, the base material 11 is worn by sliding with the hard scale 10A, so that the base material 11 might be damaged in some cases. By contrast, in the present embodiment, since the coating film 12 having a Co content appropriately adjusted is formed as a wear resistant layer on the forming surface 11A of the base material 11, it is possible to suppress wear of the base material 11 due to sliding with the scale 10A and damage caused by the wear. By the foregoing procedure, the steel plate 10 is formed and quench-hardened to complete the hot forming method according to the present embodiment.

[Function and Effect]

Next, description will be made of features and functions and effects of the coating film 12, the hot-forming die 1, and the hot forming method according to the present embodiment.

The coating film 12 is a coating film formed on the base material as a wear resistant layer in the hot-forming die 1 for hot-forming of a body to be formed which is made of steel (the steel plate 10). The coating film 12 is made of WC and 3 wt % or more and 15 wt % or less of remaining Co. The hot-forming die 1 comprises the base material 11 having the forming surface 11A and the coating film 12 which is formed on the forming surface 11A. The hot forming method includes Step S10 of heating the steel plate 10 and Step S20 of forming the steel plate 10 heated in Step S10 using the hot-forming die 1.

The coating film 12 is made of WC and 3 wt % or more and 15 wt % or less of remaining Co, and functions as an excellent wear resistant layer in the hot-forming die 1. When the Co content is less than 3 wt %, the coating film is fragile, so that at the time of hot-forming, the coating film breaks off to advance damage. On the other hand, when the Co content exceeds 15 wt %, the amount of soft Co is excessive in the coating film so that a wearing speed is increased. With the Co content being appropriately adjusted, the coating film 12 is allowed to function as an excellent wear resistant layer in the hot-forming die 1. Specifically, even when hot-forming of the steel plate 10 is conducted using the hot-forming die 1, it is possible to suppress the scale 10A formed on the surface of the steel plate 10 from wearing and damaging the die. Additionally, according to the hot forming method using the hot-forming die 1, since durability of the die can be improved by suppressing damage caused by wear of the die, a maintenance interval of the die can be increased, thereby enabling efficient hot-forming.

The coating film 12 can be formed by a thermal spraying method. When a cross-section of the coating film 12 is observed at a 2000× magnification, sizes of 95% or more of particles of tungsten carbide contained in the coating film 12 are the sizes included in a circle with a diameter of 10 μm. This prevents the particles from dropping off due to sliding of the coating film 12 and the steel plate 10, thereby enabling improvement in wear resistance.

The steel plate 10 includes 0.5 wt % or more and 3 wt % or less of Si and 0.05 wt %/o or more and 1.0 wt % or less of Cr, and is formed of steel including remaining iron and impurities. When Si and Cr are included in the steel plate 10, components of Fe₂O₃ and Fe₃O₄ are richer in the scale 10A formed on the steel plate 10 than that of FeO. Since these scale components are components harder than FeO, an amount of wear of the die caused by the scale 10A is liable to be increased in hot-forming of the steel plate 10 including Si and Cr. By contrast, the hot-forming die 1 in which the coating film 12 is formed as a wear resistant layer prevents an increase in an amount of wear also in hot-forming of the steel plate 10 including Si and Cr.

### Other Embodiments

While the description has been made of the embodiment with respect to the case where the coating film 12 is formed by the arc ion plating method or the sputtering method, the method is not limited thereto. For example, a thermal spraying method can be used in which a WC—Co sintered body with a Co content adjusted to be 3 wt % or more and 15 wt % or less is used as a thermal spraying member, and the thermal spraying member is heated to be sprayed to the base material 11 at a high speed. More specifically, flame thermal spraying may be used in which with combustion flame of oxygen and fuel gas used as a heat source, a thermal spraying member is melted, or plasma thermal spraying may be used which uses plasma generated by electric discharge between electrodes as a heat source. Since a film-forming speed can be increased according to the thermal spraying method as compared with a PVD method, the coating film 12 can be efficiently formed in a short time period even when the thickness T1 (e.g., 50 μm or more) is large.

In the embodiment, a shape of the hot-forming die 1 is not limited to that shown in FIG. 1 but allows for various shapes according to a shape into which the steel plate 10 is formed. Additionally, a body to be formed is not limited to the steel plate 10, but various steel members can be used which are processed by hot-forming.

### EXAMPLES

### Example 1

Experiment was conducted for evaluating wear resistance to a steel member on which a scale was formed.

A ball of JIS SKD 11 (diameter of 10 mm, HRC60) was prepared, and coating films shown in Nos. 1 to 11 in Table 1 below were formed on a surface of the ball. In No. 1, no coating film was formed. In No. 2, a coating film made of TiAlN was formed. In No. 3, a coating film made of WC and including no Co was formed. In Nos. 4 to 11, coating films made of 1 to 20 wt % of Co and WC were formed. In Nos. 2 and 11, the films were formed by the PVD method, and in Nos. 3 to 10, the films were formed by the thermal spraying method.

On the other hand, a steel plate including 0.22 wt % of C and 1.2 wt % of Si was prepared, and the steel plate was heated to 950° C. in atmosphere and thereafter left to be cooled in atmosphere, thereby producing a scale on the steel plate.

Slide test was conducted by sliding balls on which the coating films of Nos. 1 to 11 shown in Table 1 below were formed and a steel plate on which a scale was produced and measuring an area of a wear part formed on a contact part between each ball and the steel plate. In the slide test, with a vertical load of 5N, a slide speed of 0.1 m/s (reciprocating motion with a slide width of 30 mm), and a slide distance of 72 m, an area of the wear part was measured to evaluate wear resistance. Table 1 shows results of the measurement.

TABLE 1

| | | | Film | Wear |
|---|---|---|---|---|
| | Coating | Film forming | thickness | area |
| Number | film | method | (μm) | (mm²) |
| 1 | Without coating film | — | — | 1 |
| 2 | TiAlN | PVD | 5 | 0.5 |
| 3 | WC | Thermal spraying | 100 | 0.4 |
| 4 | Co(1 wt %) + WC | Thermal spraying | 100 | 0.4 |
| 5 | Co(3 wt %) + WC | Thermal spraying | 100 | 0.3 |
| 6 | Co(5 wt %) + WC | Thermal spraying | 100 | 0.125 |
| 7 | Co(10 wt %) + WC | Thermal spraying | 100 | 0.15 |
| 8 | Co(12 wt %) + WC | Thermal spraying | 100 | 0.2 |
| 9 | Co(17 wt %) + WC | Thermal spraying | 100 | 0.4 |
| 10 | Co(20 wt %) + WC | Thermal spraying | 100 | 0.5 |
| 11 | Co(5 wt %) + WC | PVD | 5 | 0.125 |

As is clear from Table 1, it was found that when the coating film whose Co content was 3 wt % or more and 15 wt % or less was formed (Nos. 5 to 8, and 11), the wear area was 0.3 mm² or less, so that good wear resistance was exhibited to the steel plate on which a scale was produced. Additionally, while when the PVD method was used, an upper limit of the film thickness was on the order of 10 μm (in Nos. 2 and 11, the film thickness was 5 μm), the thermal spraying method enabled a coating film with the film thickness of 100 μm or more to be formed (in Nos. 3 to 10, the film thickness was 100 μm), and forming a coating film with a large film thickness enabled a life of a coating film to be further increased.

### Example 2

A ball of JIS SKD 11 was prepared, on a surface of which, a coating film (a film thickness of 100 μm) made of Co (7 wt %) and WC was formed by the thermal spraying method, or a coating film (a film thickness of 10 μm) made of TiAlN was formed by the PVD method. Additionally, as shown in Nos. 1 to 11 of Table 2 below, steel plates having different Si and Cr contents were prepared, and heated at a high temperature in atmosphere similarly to Example 1 to produce scales on the steel plates. Then, the slide test of ball to the each steel plate was conducted to examine effects of a composition of the steel plate exerted on wear resistance of the coating film. Table 2 shows results.

TABLE 2

| | Composition of steel plate | | CO(7 wt %) + | |
|---|---|---|---|---|
| | Si content | Cr content | WC | TiAlN |
| Number | (wt %) | (wt %) | Wear area (mm²) | |
| 1 | 0 | 0 | 0.06 | 0.08 |
| 2 | 0.35 | 0 | 0.08 | 0.1 |
| 3 | 0.5 | 0 | 0.1 | 0.3 |
| 4 | 1 | 0 | 0.125 | 0.4 |
| 5 | 1.5 | 0 | 0.15 | 0.5 |
| 6 | 2.5 | 0 | 0.3 | 0.6 |
| 7 | 3 | 0 | 0.3 | 0.6 |
| 8 | 4 | 0 | 0.3 | 0.4 |
| 9 | 1 | 0.5 | 0.15 | 0.4 |
| 10 | 1 | 1 | 0.2 | 0.4 |
| 11 | 1 | 1.5 | 0.3 | 0.5 |

As is clear from Table 2, in either case where a coating film made of Co (7 wt %) and WC was formed and a case where a coating film made of TiAlN was formed, with an increase in Si and Cr contents, an area in a worn part of the coating film was increased. However, in a case where a coating film made of TiAlN was formed, when the Si content was 0.5 to 3 wt % and the Cr content was 0 wt % (Nos. 3 to 7), and when the Si content was 1 wt % and the Cr content was 0.5 to 1 wt % (Nos. 9 and 10), the wear area was increased to 0.3 mm² or more, and in a case where a coating film made of Co (7 wt %) and WC was formed, the wear area was suppressed to be 0.3 mm² or less to exhibit excellent wear resistance.

### Example 3

As shown in Nos. 1 to 6 of Table 3 below, with a particle size (maximum particle size (μm)) of WC powder varied which was used as a raw material for thermal spraying, a WC—Co coating film was formed on a surface of a ball of JIS SKD 11 by the thermal spraying method similarly to Example 1. A thickness of the WC—Co coating film was set to be 100 μm.

Next, the formed WC—Co coating film was cut in the thickness direction and resin was embedded to conduct polishing processing with respect to a cut surface. Then, a section of the WC—Co coating film was observed by SEM at a 2000× magnification. Then, a maximum length of an individual WC particle in an observation field of vision was measured. On the basis of a result of the measurement, a rate (%) of the number of the WC particles included in a circle with a diameter of 10 μm was calculated relative to the total number of WC particles in the observation field of vision.

Thereafter, with respect to each sample of Nos. 1 to 6 in Table 3 below, slide test was conducted under the same conditions as those of Example 1 to compare amounts of wear (mm²).

TABLE 3

| | Maximum | Rate (%) of WC | | |
|---|---|---|---|---|
| | particle | particles included | Co | Wear |
| | size (μm) of | in circle with | amount | amount |
| Number | WC particle | diameter of 10 μm | (wt %) | (mm²) |
| 1 | 50 | 90 | 6 | 0.2 |
| 2 | 20 | 95 | 6 | 0.17 |
| 3 | 10 | 100 | 6 | 0.14 |
| 4 | 5 | 100 | 6 | 0.1 |
| 5 | 3 | 100 | 8 | 0.16 |
| 6 | 1 | 100 | 13 | 0.2 |

As is clear from Table 3, it was found that when a rate of WC particles included in a circle with a diameter of 10 μm was 95% or more (Co amount was 6 wt % or 8 wt %), as compared with a case where the rate was less than 95%, a wear area (mm²) was small to improve wear resistance. It can be considered that this is because drop-off of WC particles on a slide surface of a coating film can be prevented by reducing an individual WC particle constituting the coating film in size.

1: A coating film,
comprising: tungsten carbide and 3 weight % or more and 15 weight % or less of cobalt,
wherein the coating film is suitable as a wear resistant layer in a die for hot forming a body made of steel.

2: The coating film according to claim 1, obtained by a thermal spraying method, wherein
when a cross-section of the coating film is observed at a 2000× magnification, sizes of 95% or more of particles of tungsten carbide contained in the coating film are the sizes included in a circle with a diameter of 10 μm.

3: The coating film according to claim 1, wherein
the body made of steel comprises 0.5 weight % or more and 3 weight % or less of silicon.

4: The coating film according to claim 1, wherein
the body made of steel comprises 0.05 weight % or more and 1.0 weight % or less of chrome.

5: The coating film according to claim 1, wherein
the body made of steel comprises 0.15 weight % or more and 0.35 weight % or less of carbon.

6: A hot-forming die for hot forming a body made of steel, the hot-forming die comprising:
a base material including a forming surface; and
the coating film according to claim 1 formed on the forming surface.

7: A hot forming method, comprising:
heating a body made of steel to obtain a heated body; and
forming the heated body
in the hot-forming die according to claim 6.

8: The coating film according to claim 2, wherein
the body made of steel comprises 0.5 weight % or more and 3 weight % or less of silicon.

9: The coating film according to claim 2, wherein
the body made of steel comprises 0.05 weight % or more and 1.0 weight % or less of chrome.

10: The coating film according to claim 2, wherein
the body made of steel comprises 0.15 weight % or more and 0.35 weight % or less of carbon.

11: A hot-forming die for hot forming a body made of steel, the hot-forming die comprising:
a base material including a forming surface; and
the coating film according to claim 2 formed on the forming surface.
